(19) United States
(12) Patent Application Publication
(10) Pub. No.: US 2013/0316095 A1
(43) Pub. Date: Nov. 28, 2013

(54) RETAINING DEVICE FOR SUBSTRATES AND METHOD FOR COATING A SUBSTRATE

(71) Applicants: Stefan Reber, Gundelfingen (DE); Norbert Schillinger, Ihringen (DE); Martin Arnold, Gundelfingen (DE); David Pocza, Freiburg (DE)

(72) Inventors: Stefan Reber, Gundelfingen (DE); Norbert Schillinger, Ihringen (DE); Martin Arnold, Gundelfingen (DE); David Pocza, Freiburg (DE)

(73) Assignee: FRAUNHOFER-GESELLSCHAFT ZUR FOERDERUNG DER ANGEWANDTEN FORSCHUNG E.V., Munich (DE)

(21) Appl. No.: 13/993,176

(22) PCT Filed: Dec. 19, 2011
(86) PCT No.: PCT/EP2011/006419

§ 371 Date: Aug. 6, 2013

(30) Foreign Application Priority Data
Dec. 22, 2010 (DE) 10 2010 055 675.0

(51) Int. Cl. C23C 16/458

(52) U.S. Cl. CPC C23C 16/458
USPC 427/569; 118/500; 118/503; 427/248.1

(57) ABSTRACT

The invention relates to a retaining device for substrates to be coated, which device comprises a contact surface for the substrate to be coated. The retaining device is for example configured as a plate on which the substrate rests and which has one or more apertures, e.g. drilled holes, grooves etc. has, through which a pressure gradient can be set between the face of the substrate and the opposite face of the retaining device. In this way a temporary fixing of the substrate by suction onto the retaining device is possible. The invention also relates to a method for coating a substrate which uses the retaining device according to the invention.

### PRIORITY INFORMATION

The present invention is a 371 National Phase Application of PCT/EP2011/006419 filed on Dec. 19, 2011 that claims priority to German Application No. 102010055675.0 filed on Dec. 22, 2010, which are incorporated herein by reference in their entireties.

### BACKGROUND OF THE INVENTION

The present invention relates to a retaining device for substrates to be coated, which comprises a support surface for the substrate to be coated. The retaining device is configured for example as a plate on which the substrate is supported and which thereby has one or more apertures, e.g. through-borings, grooves, etc., via which a pressure gradient can be set between substrate side and the oppositely situated side of the retaining device. As a result, a temporary fixing of the substrate by suction on the retaining device is possible. Likewise, the present invention relates to a method for coating a substrate which uses the retaining device according to the invention.

In order to reduce the cost of coatings, a coating plant must be able to be scaled as well as possible. The following requirements are thereby revealed:
a) Particles which are produced by the coating process or a possible transporting process must not fall on the surface of the area to be coated. This produces defects in the coating which, according to the application, can lead to complete failure of the product.
b) The area to be coated should not be partially shaded by mountings such that no coating can take place locally. Also for this reason, the same disadvantages as described under a) can arise.
c) The deposition geometry (e.g. spacing relative to the source, volume of the coating chamber) should be as constant as possible. Non-constant deposition geometry leads for example to non-homogeneous deposition rates.

The retaining devices for substrates which are known to date provide for example clamps or similar in order to secure a substrate on the retaining device for coating. Such a retaining device provided with a substrate can then be disposed face-down.

For example in the case of PECVD plants, the substrate is at present routinely disposed with the area to be coated facing downwards and is coated from below. It is consequently achieved that particles cannot fall on the surface.

However, it is hereby disadvantageous that, in the case of a mechanical fixing of the substrate by clamps etc., partial shading of the substrate is unavoidable so that, during the coating process, the complete area of the substrate is not always available for the coating.

As an alternative hereto, the face-up arrangement of substrates is possible. The area to be coated is thereby orientated upwards. The substrate can hence be supported on the retaining device without shading of the area to be coated. However, it is hereby disadvantageous that the possibility cannot be precluded of particles falling onto the surface of the substrate to be coated as a result of gravity and hence inadequate levels of purity in the coating process can be obtained.

### SUMMARY OF THE INVENTION

Starting herefrom, it is hence the object of the present invention to indicate a retaining device for mounting substrates in a coating plant, which makes it possible to retain substrates to be coated reliably without the substrates being shaded by mechanical retaining devices and, on the other hand, ensures that particles do not fall onto the substrate as a result of gravity if the latter is disposed face-up as would be the case here. Likewise, it is the object of the present invention to indicate a corresponding coating plant and also a method for coating a substrate.

This object is achieved, with respect to the retaining device, by the features of patent claim 1, with respect to the coating plant, by the features of patent claim 6 and also, with respect to the method for coating the substrate, by the features of patent claim 8. Purposes of use are indicated by patent claim 12. The respective dependent patent claims thereby represent advantageous developments.

According to the invention, a retaining device for substrates to be coated is hence described, which retaining device comprises a support device for the substrate to be coated, having a front-side of a planar configuration for supporting the substrate and also a rear-side situated opposite the front-side. The retaining device according to the invention is distinguished by at least one continuous aperture which connects the two sides of the support device being present, via which a pressure control of the gas pressure which prevails between the two sides of the support device is possible.

According to the invention, it is hence made possible by the retaining device that a substrate to be coated is supported on the support device. Preferably, substrates to be coated thereby have a planar configuration, likewise the surface of the support device on which the substrate is supported is accordingly configured corresponding to the surface of the substrate, i.e. likewise has a planar configuration, so that the substrate can be supported on the surface of the support device in a form fit. Via the apertures which are present in the support device, a reduced pressure can now be applied, so that, via the reduced pressure which prevails on the side of the support device orientated away from the substrate side, the substrate can be pressed or suctioned onto the support device and hence can be fixed. Hence a mounting of the substrate in all possible spatial directions, i.e. for example also face-down, is possible so that, in the previously described manner, a substrate can be fixed at least temporarily with the retaining device according to the invention during a coating process.

The essence of the invention hence resides in
suitable substrate holders being disposed vertically or horizontally (face-down),
the pressure ratios in the coating plant being established such that a higher gas pressure prevails on the side to be coated than on the rear-side of the substrate holder,
a pressure equalisation between rear-side of the wafer and rear-side of the substrate holder being achieved by suitable borings in the substrate holder,
   and hence the substrate being pressed onto the carrier by the increased gas pressure.

By means of the invention, the initially mentioned problems are therefore completely eliminated; i.e.:
Particles essentially do not fall on the surface since the substrates are disposed vertically or face-down, the “aperture face” of the substrates relative to the force of gravity is ideally zero, in reality, very low, i.e. reducing the risk of contamination of the surface with particles.
Shading, of the area to be coated, by mechanical mountings of the substrate can be avoided completely. Any possibly present mechanical mountings which retain the substrate outside the deposition region do not have an effect during the deposition. All-over coating of the area is hence made possible without shading by mountings/pins.
As a result of the vertical arrangement, the deposition region can be scaled easily. Extensions in the vertical direction leave the deposition geometry constant, in contrast for example to tilted substrate arrangements. Hence there are no restrictions with respect to size-scalability.

A preferred embodiment provides that the support device has 2 to 100, preferably 2 to 10, continuous apertures extending from the one side to the other. In particular in the case of a high number of apertures, these are called “porous holders”.

A device for producing a low pressure can be connected on the rear-side to the at least one aperture. This device can be configured for example as a fan, pump etc., the only crucial thing thereby is that a low pressure can be formed with the device, which can be applied opposite the interior, i.e. opposite the substrate side of the support device. The device for producing the low pressure can thereby be connected in the normal manner to the apertures, for example by hoses etc. Likewise, it is possible that the side of the support device orientated away from the substrate side delimits a space which can be supplied with low pressure and the thus applied low pressure continues onto the substrate side.

In a preferred embodiment, the invention is distinguished further by the support device being delimited by at least two oppositely situated retaining elements. The retaining elements can be configured for example as arms, grooves, clamps or hooks.

Preferably, at least two arms which are disposed opposite each other are thereby provided, which arms are delimited by walls and inner edges, the support device and the arms delimiting a region into which the substrate to be coated can be received. The internally situated walls of the arms, orientated towards the region for the substrate, thereby have an angle, relative to the support surface for the substrate of the support device, of <90°. This particular embodiment of the invention provides that two arms are disposed on both ends of the support device and can be configured also for example as grooves, clamps or hooks. It is thereby essential that the arms are inclined inwards, i.e. towards the support surface for the substrate. The substrate can hence, in the case where it is dimensioned such that it is longer than the opening defined by the edges of the arms, no longer be removed from the retaining device in the direction of the arms. The arms hence serve for securing the substrate in the case where, as described above, said substrate is not fixed by low pressure on the support surface of the support device.

Via the choice of the above-mentioned angle and the length of the arms of the retaining device, a reduction in the opening of the aperture situated between the arms can therefore be achieved. The choice of the respective angle and the length of the arms of the retaining device thereby depends upon the respective substrate. The retaining elements should be dimensioned such that the substrate does not tilt without suction.

The concrete angle or length and height of a clamp or groove hence depends upon the size of the substrate and the support surface or upon how much clearance the substrate has on the support surface.

According to the invention, a coating plant which has at least one above-described retaining device is likewise provided.

The coating plant according to the invention can preferably be configured such that the retaining device according to the invention is accommodated in a sealed coating chamber.

This coating chamber can be connected to one or more coating sources, alternatively or additionally hereto, the coating sources can however also be accommodated in the coating chamber.

The apertures of the retaining device can be connected via corresponding connections to a low pressure device, the device for producing a low pressure preferably being fitted outside the coating chamber. The connections between the apertures of the retaining device and the low pressure device can be configured also in the form of channels which are recessed for example in the wall of the coating chamber. Hence hose connections between the retaining device and the low pressure device can be avoided; this enables in particular the use of the coating device for high-temperature applications.

In a further preferred embodiment, the coating chamber is configured such that it can be opened in order to introduce corresponding substrates into the coating device or to remove them after conclusion of the coating process.

The coating source can thereby be selected for example from thermal vaporisers, PVD- and/or CVD coating sources.

Furthermore, a method for coating a substrate is indicated according to the invention, which method is distinguished by at least one substrate to be coated being introduced into a retaining device of an above-described coating plant, being fixed temporarily on the support device and also subsequently being coated.

In a preferred embodiment, the temporary fixing is effected by the gas pressure in the interior (pᵢ) being increased relative to the gas pressure in the exterior (pₐ), preferably with the device for producing a low pressure. The pressure difference must thereby be chosen such that the substrate remains fixed in every spatial orientation of the retaining device (i.e. for example even in a face-down orientation of the substrate) on the provided support surface, by the prevailing low pressure.

During the coating method, i.e. during the coating process, it is particularly advantageous if the retaining device with the fixed substrate is disposed vertically, diagonally or horizontally, the substrate to be coated being disposed with the area to be coated facing downwards in the case of the diagonal and the horizontal arrangement.

The coating can thereby be implemented in particular by means of high-temperature coating methods, CVD processes, such as e.g. PECVD methods, and also the atmospheric pressure CVD method, such as e.g. thermal APCVD, and/or PVD processes, in particular sputtering methods.

Possibilities for use both of the retaining device, of the coating plant and also of the illustrated method are found in particular in the coating, sintering and/or tempering of wafers, metal sheets and/or ceramics.

A particular advantage of the invention is that no additional mountings, such as e.g. stainless steel pins etc., are required. The retaining device hence offers advantages in particular in the high-temperature range of the above-mentioned applications.

### DETAILED DESCRIPTION OF THE ILLUSTRATED EMBODIMENTS

The present invention is described in more detail with reference to the subsequent accompanying Figures without restricting the invention to the special parameters illustrated there.

There are shown

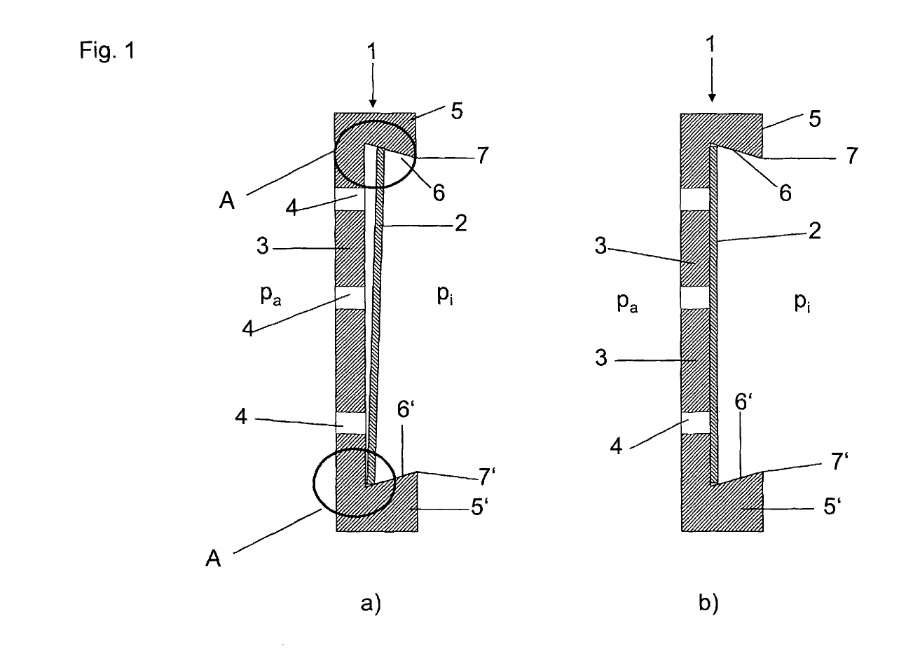

FIG. 1a+b a retaining device 1 according to the invention in a vertical arrangement before and after suction;

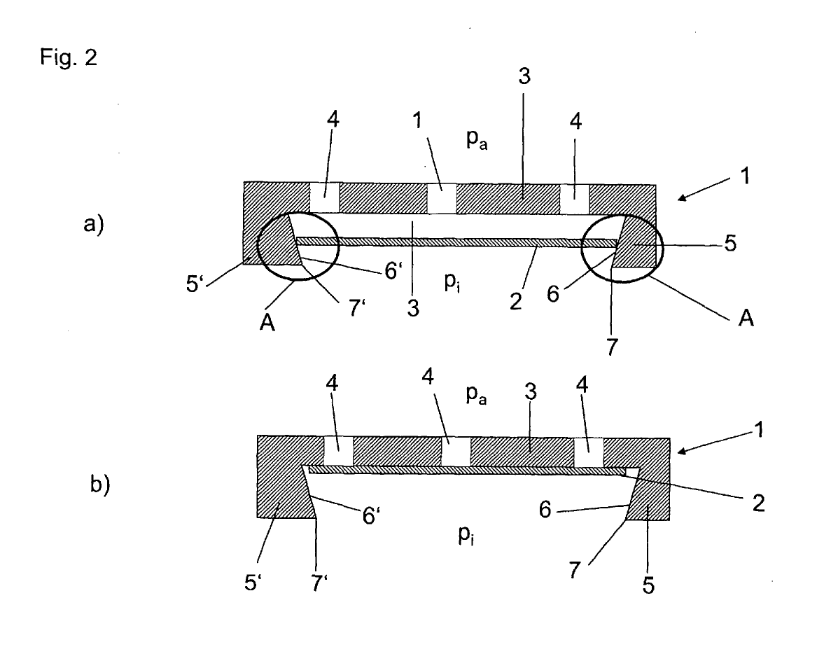

FIG. 2a+b an arrangement and also a method implementation in which a substrate can be retained horizontally face-down, before and after suction;

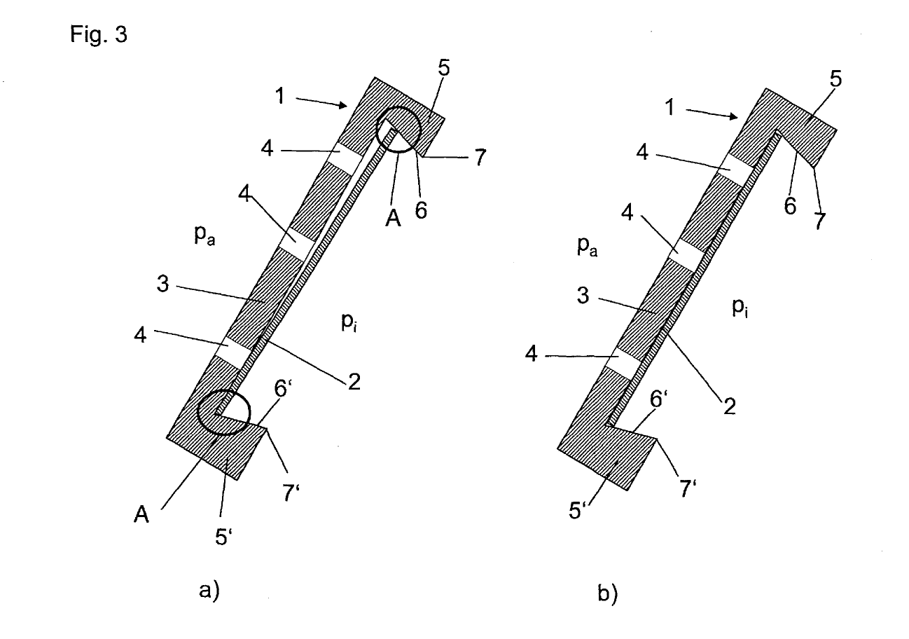

FIG. 3a+b the same situation, illustrated in FIG. 1 or 2, for the case where the substrate holder 1 is disposed at an angle, i.e. diagonally, before and after suction; and also

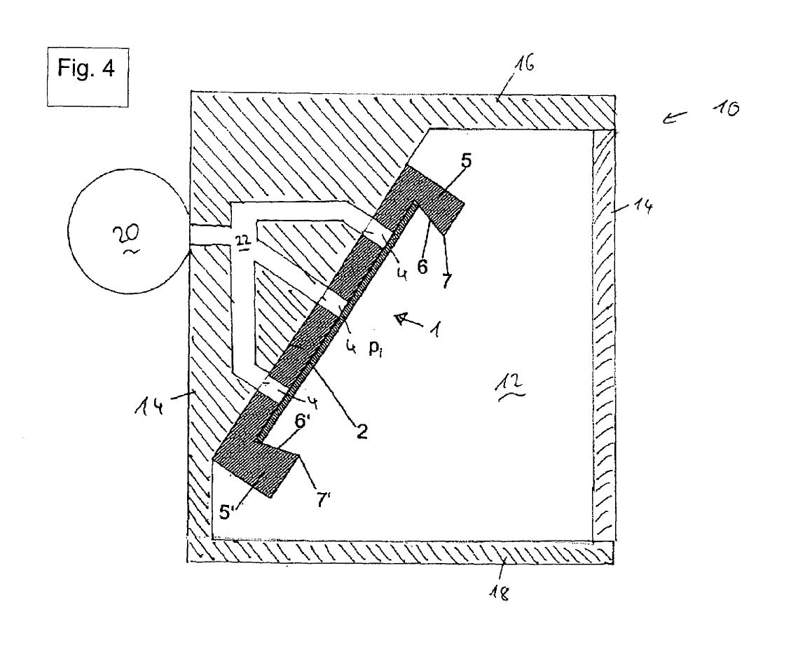

FIGS. 4+5 respectively a coating device according to the invention.

FIG. 1 shows a retaining device 1 according to the invention in a vertical arrangement, firstly before (FIG. 1a) and after (FIG. 1b) suction of the substrate. The retaining device 1 thereby comprises a support device 3 (which can also be termed substrate carrier), three apertures 4 in the form of through-borings being situated continuously through the support device 3 in the illustrated cross-section. On both sides of the support device 3, this is flanked by two arms 5, 5′ which are configured integrally with the support device 3. The arms 5, 5′ thereby have respectively an interior wall 6, 6′, which has a chamfered configuration. In the case of the device I illustrated here, the angle which the walls 6, 6′ respectively enclose with the support surface of the substrate carrier 3 for the substrate 2, is for example approx. 75°. However also larger or smaller angles are conceivable. It is likewise possible that the angles at both arms 5, 5′ are configured differently. The two walls 6, 6′ are delimited respectively by terminal inner edges 7, 7′. The spacing of the edge 7 relative to the opposite edge 7′ is, as a result of the chamfered configuration of the walls 6, 6′, smaller than the corresponding length of the support surface of the support device 3 for the substrate 2. In the case where a substrate 2 of a correspondingly large dimension is introduced into the retaining device 1 (as is the case in FIGS. 1a and 1b), direct insertion of the substrate 2 cannot hence be effected into the retaining device 1 from the right side illustrated in FIG. 1. The substrate 2 must therefore be introduced into the retaining device 1 for example at the rear in the picture plane. As a result, it is however impossible for the substrate 2 to fall out of the retaining device 1 in the direction of the arms 5, 5′. Furthermore, the gas pressure which prevails on the side of the retaining device 1 orientated away from the support surface for the substrate 2 is designated with pₐ in FIG. 1, whilst pᵢ designates the pressure which prevails on the side of the substrate. In FIG. 1a, the condition that the pressure pᵢ≦p_{Pa}—is now illustrated so that the substrate is not fixed on the support surface of the substrate holder 3. If the pressure is now adjusted such that pᵢ≧pₐ, a situation illustrated in FIG. 1b arises, that namely the substrate 2 is suctioned onto the support surface of the substrate holder 3 and fixed there via the prevailing low pressure (or a high pressure pᵢ from the perspective of the interior).

A corresponding arrangement and also a method implementation in which a substrate can be retained horizontally face-down is illustrated in FIG. 2. The same reference numbers are thereby used as already in FIG. 1. It is evident again in particular in FIG. 2a that the retaining device 1 is dimensioned such that the substrate cannot fall out of the retaining device 1. The chamfered arms 5 with the diagonally guided walls 6, 6′ are responsible for this. Here also, the substrate 2 can be connected or fixed in a form fit to the support surface of the substrate holder 3 simply by lowering the external pressure so that a situation illustrated in FIG. 2b results.

FIGS. 3a and 3b illustrate the same situation which is illustrated in FIG. 1 or 2 in the case where the substrate holder 1 is disposed at an angle, i.e. diagonally.

It is hence evident from the Figures that a quasi-universal fixing of a substrate 2 is possible by means of the retaining device 1 according to the invention. In the case where the substrate has a longer dimension in its extension than the spacing of the edges 7 and 7′, then the substrate can in addition be prevented from falling out of the retaining device 1 in the absence of a low pressure at the apertures 4.

FIG. 4 shows schematically a coating plant 10 according to the invention having a retaining device 1 according to the invention. The coating plant has a coating chamber 12 which can be formed for example by walls 14, a cover 16 and a base 18 which delimit a spatial volume. In the coating chamber 12, there are situated at least one retaining device 1 according to the invention for receiving one or more substrates 2.

The coating chamber 12 is sealed and can be connected to one or more coating sources in order to introduce a coating medium, e.g. a gas, into the spatial volume of the coating chamber. Alternatively or additionally, the coating chamber can also comprise one or more coating sources.

The retaining device 1 has apertures 4, as described above. The apertures are connected to a low pressure device 20 in order to produce a low pressure relative to the pressure in the volume of the gas chamber so as to fix the substrate in the retaining device. Advantageously, the connections of the apertures to the low pressure device are integrated in the retaining device and also in the base, cover and/or the walls of the coating chamber, for example as channels 22, so that, in the case of high-temperature coating plants, no temperature-sensitive hose- or tube connections are required. The retaining device can also be introduced into the coating chamber only for the coating process. This has the advantage that the retaining devices are easier to clean. The substrate can thereby be fitted already in the retaining device upon introduction of the retaining device. In this case, it is particularly advantageous that the substrate is secured by the retaining elements 5 before it is fixed temporarily by the low pressure.

The coating chamber can be opened in order to introduce the retaining device manually. Alternatively, the retaining device can be introduced automatically via a conveying device. The retaining device can be secured in the coating chamber by automatic or self-locking securing elements which can be detached rapidly so that they can be easily introduced and removed again after the coating process or for cleaning or maintenance.

Advantageously, the connections for the low pressure device are integrated in the base, cover and/or the walls of the coating chamber such that the connection to the low pressure device is produced readily when the retaining device is secured or is introduced via the conveying device.

In an advantageous embodiment, also walls and/or a cover can be formed entirely or partially by one or more of the retaining devices themselves. In such an embodiment, the coating chamber itself can be accommodated again particularly advantageously in a sealed spatial volume which is supplied with a low pressure.

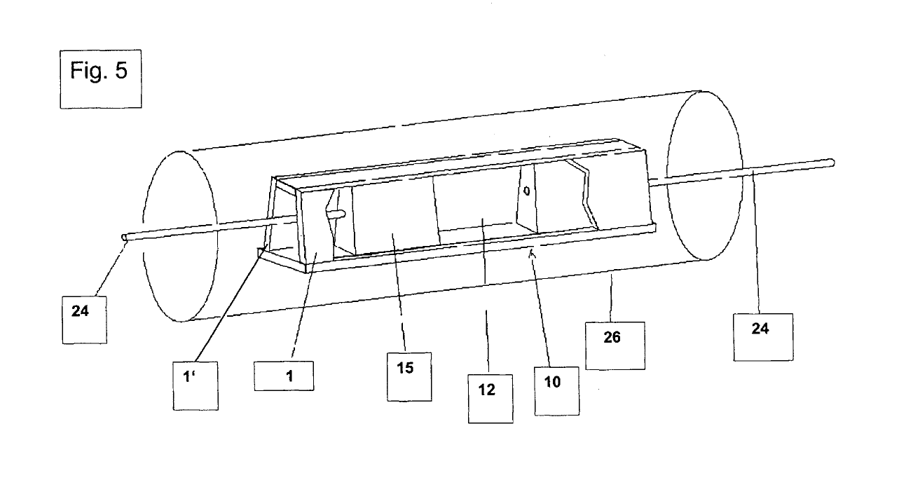

FIG. 5 shows such a particularly advantageous embodiment.

In the coating plant 10 in FIG. 5, a coating chamber 12 in the case of which two retaining devices 1, 1′ form the front and rear delimitation wall of the coating chamber 12 is shown. The front retaining device 1 is cut away in order to show the interior of the coating chamber 12. End walls 15 are provided with borings (not illustrated) to which gas supply lines 24 are connected and through which the coating medium can be supplied and removed. The coating chamber is accommodated in a pipe 26 which can be supplied with a low pressure. As a result, the substrates are fixed temporarily in the retaining devices since the apertures in the retaining devices are connected to the interior of the pipe.

What is claimed is:

1. A retaining device for substrates to be coated, comprising a support device for the substrate to be coated, which has a front-side of a planar configuration for supporting the substrate and also a rear-side situated opposite the front-side,
wherein that
at least one continuous aperture which connects the two sides of the support device is present, via which control of the gas pressure which prevails on the side of the substrate is possible.

2. The retaining device according to claim 1, wherein that the support device has 2 to 100, preferably 2 to 10, apertures.

3. The retaining device according to claim 1, wherein a device for producing a low pressure is connected on the rear-side to the at least one aperture.

4. The retaining device according to claim 1, wherein the support device is delimited by at least two oppositely situated retaining elements, the at least two retaining elements being configured preferably as arms, grooves, clamps or hooks.

5. The Retaining device according to claim 4, wherein that the retaining elements are formed by at least two arms which are disposed opposite each other and are delimited by walls and inner edges, the support device and the arms delimiting a region into which the substrate to be coated can be received and the internally situated walls of the arms, orientated towards the region for the substrate, having an angle, relative to the support surface for the substrate of the support device, of <90°.

6. A coating plant comprising at least one retaining device according to claim 1.

7. The coating plant according to claim 6, wherein that the coating plant has a tubular coating interior which has at least two retaining devices.

8. A method for coating a substrate, wherein that at least one substrate to be coated is introduced into a retaining device of a coating plant according to one of the two preceding claims, is fixed temporarily on the support device and also subsequently is coated.

9. The method according to claim 8, wherein the temporary fixing is effected by the gas pressure in the interior being increased relative to the gas pressure in the exterior, preferably with the device for producing a low pressure.

10. The method according to claim 8, wherein that the retaining device with the fixed substrate is disposed vertically, diagonally or horizontally during the coating process, the substrate to be coated being disposed with the area to be coated facing downwards in the case of the diagonal and the horizontal arrangement.

11. The method according to claim 8, wherein that the coating is effected by means of high-temperature coating methods, CVD- and/or PVD processes, in particular sputtering methods, such as e.g. PECVD methods.

12. Use of a retaining device according to claim 1, of a coating plant or of a method according to claim 8 in the coating, sintering and/or tempering of wafers, metal sheets and/or ceramics.
